(19) United States
(12) Patent Application Publication
(10) Pub. No.: US 2025/0133682 A1
(43) Pub. Date: Apr. 24, 2025

(54) MODULAR POWER SUPPLY CONNECTOR

(71) Applicant: Meta Platforms Technologies, LLC, Menlo Park, CA (US)

(72) Inventor: Chenyu Xu, Newark, CA (US)

(21) Appl. No.: 18/913,682

(22) Filed: Oct. 11, 2024

Related U.S. Application Data
(60) Provisional application No. 63/544,754, filed on Oct. 18, 2023.

(51) Int. Cl. H05K 7/14

(52) U.S. Cl. CPC H05K 7/1491; H05K 7/1492

(57) ABSTRACT

The disclosure comprises a power management system. The system includes a cable bracket that functions as a modular power connector to a chassis of a processor. The cable bracket can comprise a lock device such that the lock device to interlock the cable bracket with the chassis. The lock device is configured to engage and disengage from the chassis. The bracket can be configured to function as an electrical conduit between the chassis of the processor and a power bus bar and wherein the bracket comprises a first electrical connector configured to engage the chassis and a second electrical connector configured to engage the power bus bar. The bracket further comprises at least one lock device to secure the cable bracket to the chassis.

### CROSS REFERENCE TO RELATED APPLICATIONS

This present application claims the benefit of priority under 35 U.S.C. § 119 (e) to U.S. Provisional Application No. 63/544,754, filed Oct. 18, 2023, the disclosure of which is hereby incorporated by reference in its entirety for all purposes.

### TECHNICAL FIELD

The present disclosure generally relates to power supply management of a computing server arrangement, and in particular, modular power connection components between the chassis rack and the computing server.

### BACKGROUND

In many computer server chassis within the industry, a power cable is widely used to deliver power from rack to chassis. Typically, the power supply cable is mounted on the rear wall of the computer server chassis, which also grounds the chassis to the rack and ensures that excess electricity is safely directly out of the chassis. The power cable is normally designed to be Field Replaceable Unit (FRU) to accommodate failures.

For computer server chassis with power cable mounted on them, servicing a failed power cable requires removing the chassis from the rack. This process involves numerous steps to disassemble the computer server chassis in order to access the faulty power cable. Due to the industry trend toward higher-power components (such as CPUs and GPUs) to meet the need for better performance, the thermal envelope continues to expand. This trend leads to computer server chassis becoming taller and heavier. Today, computer server chassis have grown from 2 OU/4 OU to 7 OU/8 OU and even taller, with an increased chassis weight accordingly.

Safety standards (OSHA, for example) regulate the weight each data center technician can safely lift and handle. With the increased height and weight of the computer server chassis exceeding these safety standards, the use of a server lift is required to remove the computer server chassis from the rack. Additionally, more than one data center technician may be required to complete the repair job. Servicing a failed power cable is becoming increasingly challenging and time-consuming.

### BRIEF SUMMARY

An embodiment of the disclosure can include a device for power management. The device can comprising a cable bracket. The cable bracket can function modular power connector to a chassis of a processor. The cable bracket can comprise a lock device such that the lock device to interlock the cable bracket with the chassis. The lock device is configured to engage and disengage from the chassis. The bracket can be dimensioned to fit in a cavity defined by an external surface of the chassis. The bracket can be configured to function as an electrical conduit between the chassis of the processor and a power bus bar and wherein the bracket comprises a first electrical connector configured to engage the chassis and a second electrical connector configured to engage the power bus bar. The bracket further comprises at least one latch protrusion, wherein the latch protrusion is oriented on an exterior surface of the cable bracket, and is configured to extend from an exterior surface of the bracket to engage the chassis.

Another embodiment of the disclosure can include a power management apparatus The apparatus can include for power management a cable bracket comprising at least one power cable. The power cable can be configured to terminates between a module bus connector and a chassis connector. The apparatus can include at least one power source. In an aspect the power source can comprise rack bus bar. The module bus connector can be configured to couple to the rack bus bar. The apparatus can comprise a chassis for a processor. The chassis for the processor can define a channel that is sized to receive the cable bracket, permitting the cable bracket to engage the chassis.

Yet another embodiment of the disclosure can include a method for power management. The method can be used in a power system comprising a cable bracket comprising at least one power cable. The power cable terminates at a module bus connector and a chassis connector. The cable bracket can be configured to engage a chassis of a processor. The method can include disengaging the cable bracket from the chassis. The method can include adjusting the cable bracket. Adjusting a cable bracket can include at least one of: cleaning, repairing or replacing the cable bracket. After the completing of the adjustment, the method can include reengaging the cable bracket to the chassis.

### BRIEF DESCRIPTION OF THE DRAWINGS

The accompanying drawings, which are included to provide further understanding and are incorporated in and constitute a part of this specification, illustrate disclosed embodiments and together with the description serve to explain the principles of the disclosed embodiments. In the drawings:

FIG. 1 illustrates an isometric rear view of the computer server engaged to a rack section coupled to the supporting structure.

FIG. 2A illustrates a rear isometric view of a cable bracket. FIG. 2B illustrates a front-expanded view of the cable bracket.

FIG. 3 illustrates an isometric rear view of the computer server.

FIG. 4 illustrates an isometric rear view of the cable bracket in proximity to the computer server.

FIG. 5 illustrates an isometric rear view of the computer server engaged to a rack section.

FIG. 6 illustrates an example flow diagram of adjusting power received to a power management system.

### DETAILED DESCRIPTION

The detailed description set forth below describes various configurations of the subject technology and is not intended to represent the only configurations in which the subject technology may be practiced. The detailed description includes specific details for the purpose of providing a thorough understanding of the subject technology. Accordingly, dimensions may be provided in regard to certain aspects as non-limiting examples. However, it will be apparent to those skilled in the art that the subject technology may be practiced without these specific details. In some instances, well-known structures and components are shown in block diagram form in order to avoid obscuring the concepts of the subject technology.

It is to be understood that the present disclosure includes examples of the subject technology and does not limit the scope of the included clauses. Various aspects of the subject technology will now be disclosed according to particular but non-limiting examples. Various embodiments described in the present disclosure may be carried out in different ways and variations, and in accordance with a desired application or implementation.

In the following detailed description, numerous specific details are set forth to provide a full understanding of the present disclosure. It will be apparent, however, to one ordinarily skilled in the art, that embodiments of the present disclosure may be practiced without some of the specific details. In other instances, well-known structures and techniques have not been shown in detail so as not to obscure the disclosure.

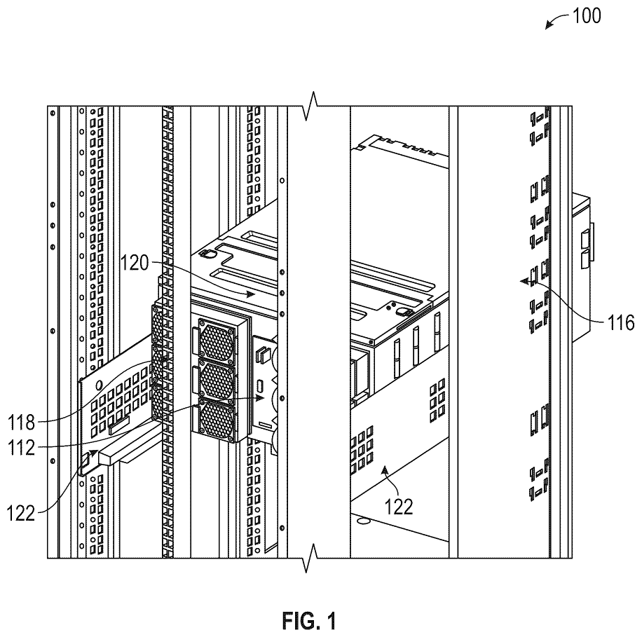

The current disclosure details configurations of an in-rack serviceable modular cable bracket supplying power to a server chassis via power connectors. The disclosure addresses the technical problem of improving the efficiency and serviceability of power cables for large and heavy computer server chassis that require in-rack servicing, while eliminating the need for a server lift or additional human assistance. This modular power cable solution is applicable to various computer server chassis designs. As depicted in FIG. 1, when the computer server chassis is in its operational position in the power shelf 116. In one aspect, the power shelf 116 can comprise an ORv3 rack. The power shelf 116 can comprise a vertical ORv3 busbar 118 to distribute DC power from a power source (not shown) to equipment mounted in the open rack via electrical power connections. In one aspect, the power shelf 116 can provide up to 18 kW of DC power (which also features a convenient blind-mate power connection). The apparatus can further include an opening 112 in the computer server chassis rear wall where the power cable bracket 102 can be installed.

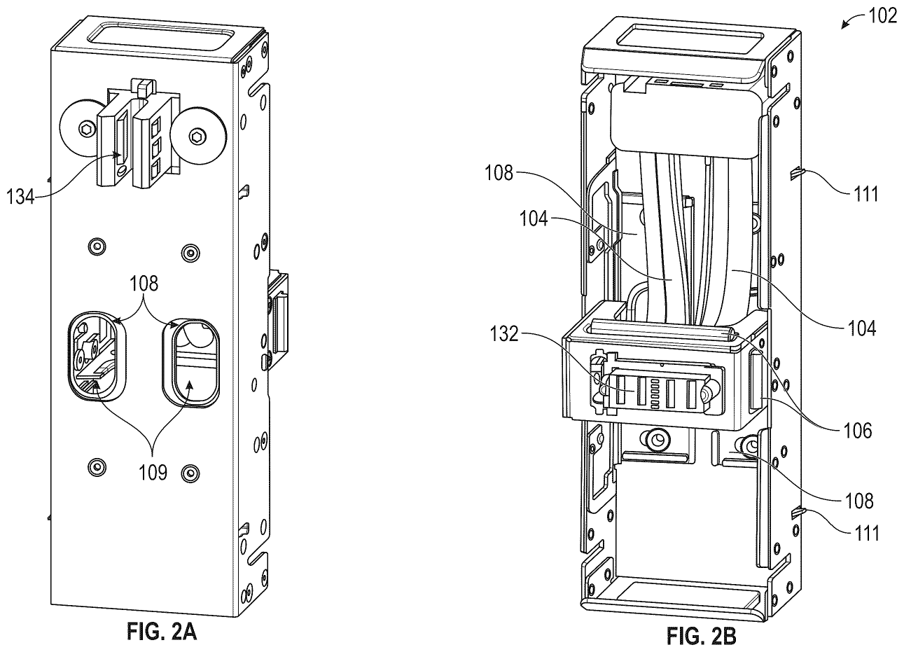

As depicted in FIGS. 2A and 2B, the apparatus 100 can include one power cable bracket 102; at least one one power cable 104 with connectors on both ends mounted on the power cable bracket 102. The power cable bracket 102 can include a power delivery board 110 where the power cable connects to the chassis, delivering power to the computer servers. The power cable can include a lock device 108 to secure the power cable bracket 102 to the chassis 120. electromagnetic interference (EMI) gaskets 106 on the power cable bracket 102 to seal off EMI leakage. The EMI gaskets 106 can be made of electrically conductive elastomers such as silicone or fluorosilicone provide environmental sealing, thermal insulation, and shielding against electromagnetic interference (EMI). The apparatus 100 can further include a chassis 120 with an opening 112 in the computer server chassis rear wall where the power cable bracket 102 can be installed. The rear wall of the chassis 120 can be equipped with EMI fingers (protrusions) 114 to ground the power cable bracket 102 to the chassis 120 (so the entire chassis is grounded to the rack). The apparatus 100 can further include a rack busbar 118 to which the power cable connects, drawing power from the rack bus bar; and at least two rack rails 122 onto which the computer server chassis 120 is seated.

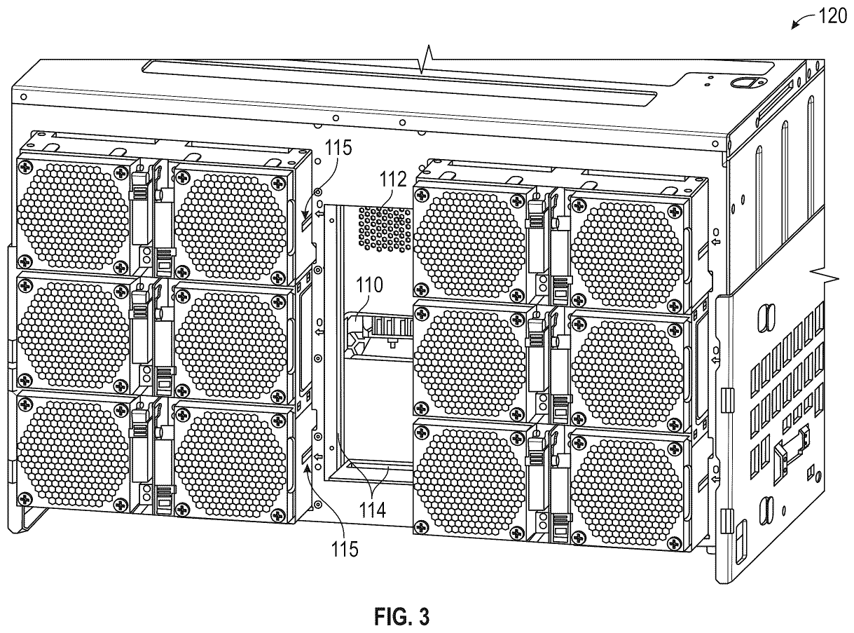

The power cable 104 can connect to rack busbar 118 and draws power from the rack busbar 118. The power cable bracket 102 can be dimensioned and structured with a sliding locking device 108 to engage and lock the power cable bracket 102 into a rear opening 112 defined by the chassis 120 of the computing server. In a further aspect, the lock device secures the surface of the bracket 102 to the chassis 120. The lock device 108 can be configured with an elastic material (e.g., metal or plastic) and without a spring, wherein the shape of a strip of the elastic material can be deformed when a force is applied and return to return to the initial shape when the force is removed. In one aspect the lock device can comprise a spring loaded latch 111, wherein the spring loaded latch 111 engages at latch notch 115 as depicted in FIG. 3. In yet another aspect the spring of the lock mechanism can comprise a torsion spring.

The technician can access the lock device 108 via the cavities 109, wherein the lock device can be disengaged by applying a force (e.g. squeezing) the lock device. Once removed from the chassis 120, the technician can either perform maintenance, cleaning and/or repair of the power cable bracket 102 or replace the power cable bracket in its entirety. Similarly, lock device can be reengaged and re-secured the engagement between the cable bracket 102 and chassis 120 by removing the force. Other embodiments of lock devices 108 as also considered such as sliding bolt, wherein the sliding bolt is a component of the cable bracket 102, and the sliding bolt is oriented to engage the same latch notch 115.

The cable bracket 102 can be dimensioned to save space and maximize fan space for cooling. During a repair after the power cable 104 fails, the power cable bracket 102 can be accessed and replaced from the hot aisle by pulling out the chassis from the rack by a certain distance along the rack rails 122 and bypassing the rack busbar 118. For safety purposes, an optional stopper (not shown) can be added to lock the chassis 120 in place after the chassis pulled out from the rack by a certain distance along the rack rails 122. Additionally, an optional busbar cover (not shown) can be applied to prevent data center technicians from touching the energized and exposed rack busbar 118 after the computer server chassis 120 is pulled out by a certain distance along the rack rails 122. The chassis pullout force is required to overcome the friction between the computer server chassis 120 and the rack rails 122, which is significantly lower compared to the effort needed to remove a large, heavy computer server chassis from the rack and disassemble it to access the faulty power cable. Therefore, in-rack serviceable modular power cable bracket 102 resolves the increasing serviceability challenges posed by large, heavy computer server chassis and greatly improves the efficiency of managing power cable repairs in the data center fleet. In alternative embodiments, the power cable 104 can comprise different configurations, including a medusa cable, y-cable, chassis cable, or the like.

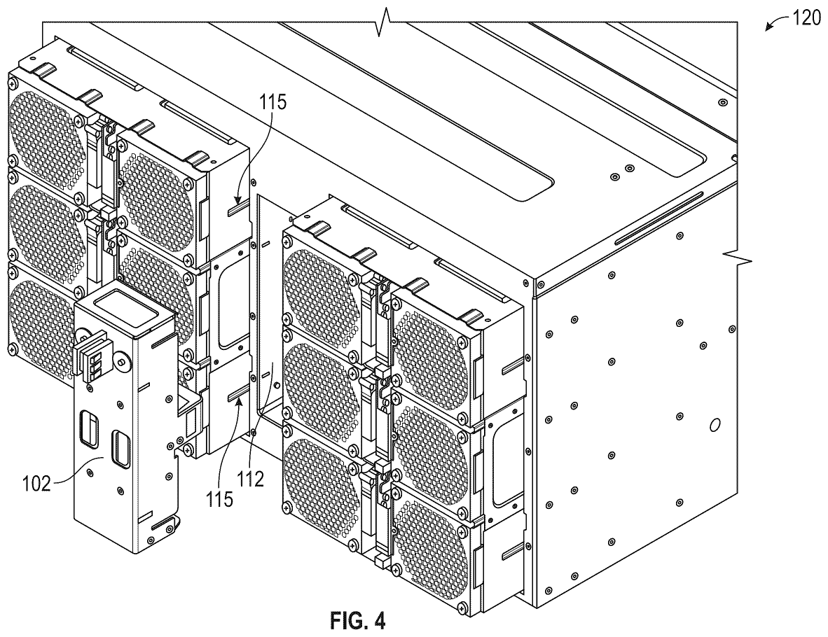

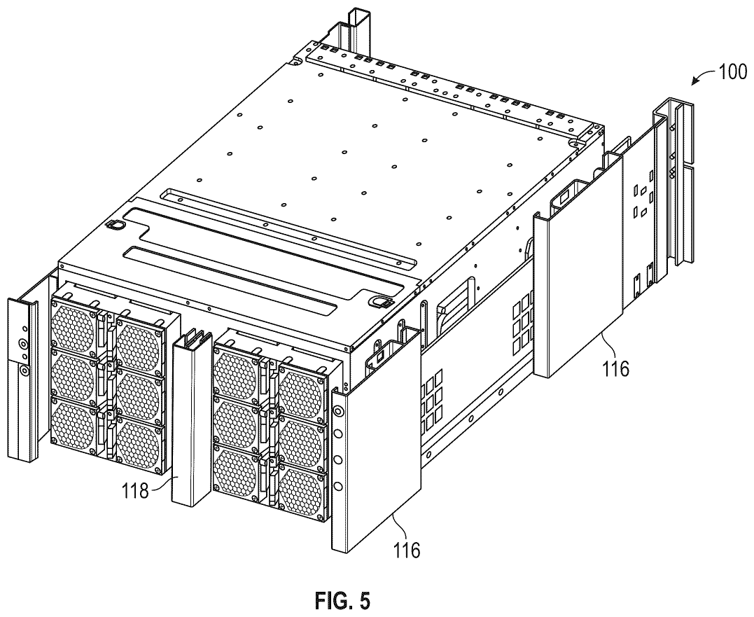

As depicted in FIG. 3, FIG. 4 and FIG. 5, once the chassis has been disengaged from the busbar 118 and pulled along the rails 122 of the rack 116, the technician can disengage the cable bracket 102 from the chassis 120 to expose the rear chassis opening 112. To complete the repair, the technician can install a new cable bracket in the recently vacated chassis opening 112, ensuring that the chassis connector 132 of cable bracket 102 properly engage the chassis power delivery board 110. To secure the connection between the cable bracket 102 and the chassis 120, the lock device 108 can be reengaged. The technician can then complete the reinstallation by pushing the chassis 120 back into its original location along the rack rails 122, wherein the cable bracket 102 engages and electrically connects to the busbar 118 via the module bus connector 134. In a further aspect, the system can comprise multiple module bus connectors to supply additional power from the bus bar 118 to the server chassis 120.

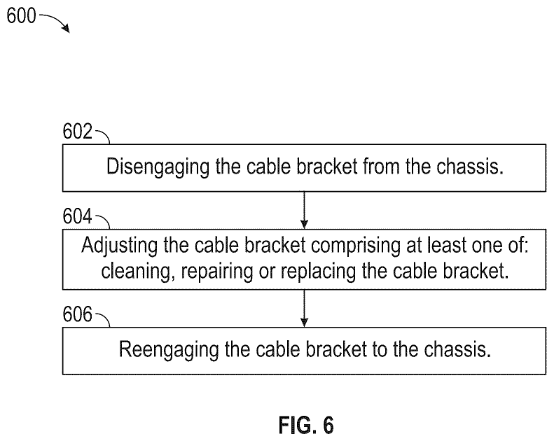

FIG. 6 illustrates an example flow diagram (e.g., process 600) for adjusting power to a power management system. For explanatory purposes, the example process 600 is described herein with reference to one or more of the figures above. Further for explanatory purposes, the steps of the example process 600 are described herein as occurring in serial, or linearly. However, multiple instances of the example process 600 may occur in parallel. At a step 602, the cable bracket can be disengaged from the chassis of the processor. The cable bracket can comprise a lock device that secures the cable bracket to the chassis of the processor. Disengaging the bracket can comprise deactivating the lock device by applying pressure to the lock device, causing protrusions of the lock device to retract from engagement in the chassis of the processor. Step 602 can further include disconnecting the cable bracket from the electrical connector coupling the cable bracket to the chassis of the processor and disconnecting the cable bracket from a second electrical connector couple the cable bracket to a power bus bar. At step 604, the cable bracket can be adjusted. The adjustment of the cable bracket can further include any one of cleaning, repairing or replacing the cable bracket. At step 606, the cable bracket can be reengaged to the chassis.

The subject technology is illustrated, for example, according to various aspects described above. The present disclosure is provided to enable any person skilled in the art to practice the various aspects described herein. The disclosure provides various examples of the subject technology, and the subject technology is not limited to these examples. Various modifications to these aspects will be readily apparent to those skilled in the art, and the generic principles defined herein may be applied to other aspects. Moreover, nothing disclosed herein is intended to be dedicated to the public regardless of whether such disclosure is explicitly recited in the above description

A reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter genders (e.g., her and its) and vice versa. Headings and subheadings, if any, are used for convenience only and do not limit the invention.

The word “exemplary” is used herein to mean “serving as an example or illustration.” Any aspect or design described herein as “exemplary” is not necessarily to be construed as preferred or advantageous over other aspects or designs. In one aspect, various alternative configurations and operations described herein may be considered to be at least equivalent. To the extent that the terms “include,” “have,” or the like is used in the description or the claims, such term is intended to be inclusive in a manner similar to the term “comprise” as “comprise” is interpreted when employed as a transitional word in a claim.

As used herein, the phrase “at least one of” preceding a series of items, with the term “or” to separate any of the items, modifies the list as a whole, rather than each item of the list. The phrase “at least one of” does not require the selection of at least one item; rather, the phrase allows a meaning that includes at least one of any one of the items, and/or at least one of any combination of the items, and/or at least one of each of the items. By way of example, the phrase “at least one of A, B, or C” may refer to: only A, only B, or only C; or any combination of A, B, and C.

A phrase such as an “aspect” does not imply that such an aspect is essential to the subject technology or that such an aspect applies to all configurations of the subject technology. A disclosure relating to an aspect may apply to all configurations or one or more configurations. An aspect may provide one or more examples. A phrase such as an aspect may refer to one or more aspects, and vice versa. A phrase such as “embodiment” does not imply that such embodiment is essential to the subject technology or that such embodiment applies to all configurations of the subject technology. A disclosure relating to an embodiment may apply to all embodiments or one or more embodiments. An embodiment may provide one or more examples. A phrase such as an embodiment may refer to one or more embodiments and vice versa. A phrase such as a “configuration” does not imply that such configuration is essential to the subject technology or that such configuration applies to all configurations of the subject technology. A disclosure relating to a configuration may apply to all configurations or one or more configurations. A configuration may provide one or more examples. A phrase such as a configuration may refer to one or more configurations, and vice versa.

In one aspect, unless otherwise stated, all measurements, values, ratings, positions, magnitudes, sizes, and other specifications that are set forth in this specification, including in the clauses that follow, are approximate, not exact. In one aspect, they are intended to have a reasonable range that is consistent with the functions to which they relate and with what is customary in the art to which they pertain. It is understood that some or all steps, operations, or processes may be performed automatically without the intervention of a user. Method clauses may be provided to present elements of the various steps, operations, or processes in a sample order, and are not meant to be limited to the specific order or hierarchy presented.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products. Other variations are within the scope of the following claims.

What is claimed is:

1. A device comprising a bracket and a lock device such that the lock device is configured to engage and disengage from a chassis, wherein the bracket is dimensioned to fit in a cavity defined by the chassis, and wherein the bracket comprises a first electrical connector configured to engage the chassis and a second electrical connector.

2. The device of claim 1, wherein the first electrical connector is configured to engage the chassis.

3. The device of claim 1, wherein the second electrical connector is configured to engage a bus bar power connector.

4. The device of claim 1, wherein the bracket further comprises an electromagnetic interference gasket.

5. The device of claim 1, wherein the bracket is further comprises at least one latch protrusion, wherein the protrusions are oriented to extend from an exterior surface of the bracket to engage the chassis.

6. An apparatus for power management comprising:
a cable bracket comprising at least one power cable, wherein the power cable terminates between a module bus connector and a chassis connector;
at least one rack busbar configured to connect to a module bus connector;
a chassis configured to couple to the chassis connector; and
the module bus connector coupled to a power source.

7. The apparatus of claim 6, wherein the cable bracket comprises a lock device to secure the cable bracket to the chassis.

8. The apparatus of claim 7, wherein the lock device is spring loaded.

9. The apparatus of claim 6, wherein the cable bracket further comprises an electromagnetic interference (EMI) gasket.

10. The apparatus of claim 9, wherein the chassis further comprises a plurality of EMI protrusions, wherein the plurality of EMI protrusions are oriented on the chassis to engage the EMI gasket.

11. A method for power management, a cable bracket comprising at least one power cable, wherein the power cable terminates at a module bus connector and a chassis connector; at least one rack busbar configured to connect to a module bus connector; a chassis configured to couple to the chassis connector; and the module bus connector coupled to a power source, the method comprising:
disengaging the cable bracket from the chassis;
adjusting the cable bracket comprising at least one of: cleaning, repairing or replacing the cable bracket; and
reengaging the cable bracket to the chassis.
